(19) United States
(12) Patent Application Publication
(10) Pub. No.: US 2020/0276619 A1
(43) Pub. Date: Sep. 3, 2020

(54) CLEANING MEMBER ATTACHING PART, CLEANING MEMBER ASSEMBLY AND SUBSTRATE CLEANING APPARATUS

(71) Applicant: Ebara Corporation, Tokyo (JP)

(72) Inventors: Shuji UOZUMI, Tokyo (JP); Toru MARUYAMA, Tokyo (JP); Yasuyuki MOTOSHIMA, Tokyo (JP)

(73) Assignee: Ebara Corporation, Tokyo (JP)

(21) Appl. No.: 16/750,859

(22) Filed: Jan. 23, 2020

(30) Foreign Application Priority Data
Feb. 4, 2019 (JP) 2019-017549

(51) Int. Cl. B08B 3/04; B08B 1/00; B08B 1/04; H01L 21/67

(52) U.S. Cl. CPC B08B 3/04; B08B 1/007; B24B 37/345; H01L 21/67046; H01L 21/67051; B08B 1/04

(57) ABSTRACT

In one embodiment of the present invention, a cleaning member 90 is attached to the surface of a cleaning member attaching part 10. The cleaning member attaching part 10 has a main body 20, a cleaning liquid introduction part 30 extending inside the main body 20, and a plurality of cleaning liquid supply holes 40 communicating with the cleaning liquid introduction part 30. The cleaning liquid introduction part 30 is configured such that cleaning liquid flows in from a first end part 11 side, and an area proportion of the cleaning liquid supply holes 40 in a second region located on a second end part 12 side opposite to the first end part 11 to a surface of the main body 20 is larger than the area proportion of the cleaning liquid supply holes 40 in a first region located on the first end part 11 side to the surface of the main body 20.

### TECHNICAL FIELD

The present invention relates to a cleaning member attaching part used in an aspect of supplying cleaning liquid into a cleaning member, a cleaning member assembly using such a cleaning member attaching part, and a substrate cleaning apparatus.

The present application claims the priority of Japanese Patent Application No. 2019-17549 filed on Feb. 4, 2019, the contents of which are entirely incorporated by reference.

### BACKGROUND

It has been conventionally known to supply a rinse liquid (inner rinse liquid) into a cleaning member such as a roll. JP 2000-301079 A discloses having a substrate holding unit that holds a substrate while rotating the substrate, a cleaning tool that scrubs the surface to be cleaned of the substrate, and a cleaning tool holding unit that holds the cleaning tool rotatably around its axis, and supplying inner rinse liquid into the cleaning tool.

### SUMMARY

Even if the inner rinse liquid is supplied in this manner, the amount of the rinse liquid discharged from a sponge of the cleaning tool may vary in the longitudinal direction of the cleaning tool. For example, even if the inner rinse liquid is supplied at a supply rate of 450 ml/min, the inner rinse liquid may not be discharged from the sponge of the cleaning tool but may flow backward and run out of the cleaning tool without passing through the sponge.

The present invention provides a cleaning member attaching part and the like that suppresses variations in the discharge amount of a supplied cleaning liquid from an inside of the cleaning member and prevents the supplied cleaning liquid from flowing out without passing through the cleaning member.

### [Concept 1]

A cleaning member attaching part, on a surface of which a cleaning member is attached, may comprise:

a main body;

a cleaning liquid introduction part extending inside the main body; and

a plurality of cleaning liquid supply holes communicating with the cleaning liquid introduction part, wherein

the cleaning liquid introduction part may be configured to introduce cleaning liquid from a first end part side, and

an area proportion of the cleaning liquid supply holes in a second region on a second end part side opposite to a first end part to a surface of the main body may be larger than an area proportion of the cleaning liquid supply holes in a first region on the first end part side to the surface of the main body.

Here, the “area proportion” refers to the proportion of the average area of a plurality of openings in a total area of a predetermined region (also referred to as opening proportion). The “average area” means an average cross-sectional area of a flow path when the cleaning liquid flows out from the cleaning liquid introduction part to the cleaning member via the cleaning liquid supply holes.

### [Concept 2]

The cleaning member attaching part according to concept 1, wherein

a cross-sectional area of the cleaning liquid supply holes in the second region is larger than a cross-sectional area of the cleaning liquid supply hole in the first region.

### [Concept 3]

The cleaning member attaching part according to concept 1 or 2, wherein

a third region is provided between the first region and the second region, and

an area proportion of the cleaning liquid supply holes in the third region to the surface of the main body is larger than the area proportion of the cleaning liquid supply holes in the first region to the surface of the main body and is smaller than the area proportion of the cleaning liquid supply holes in the second region to the surface of the main body.

### [Concept 4]

The cleaning member attaching part according to concept 3, wherein

a fourth region is provided between the third region and the first region, and

an area proportion of the cleaning liquid supply holes in the fourth region to the surface of the main body is larger than the area proportion of the cleaning liquid supply holes in the first region to the surface of the main body and is smaller than the area proportion of the cleaning liquid supply holes in the third region to the surface of the main body.

### [Concept 5]

The cleaning member attaching part according to concept 4, wherein

a cross-sectional area of the cleaning liquid supply holes in the fourth region is larger than a cross-sectional area of the cleaning liquid supply hole in the first region, and

a cross-sectional area of the cleaning liquid supply holes in the third region is larger than the cross-sectional area of the cleaning liquid supply holes in the fourth region and is smaller than a cross-sectional area of the cleaning liquid supply holes in the second region.

### [Concept 6]

The cleaning member attaching part according to any one of concepts 1 to 5, wherein

a cross-sectional area of the cleaning liquid introduction part extending inside the main body corresponds to a cross-sectional area of the cleaning liquid supply holes in the second region.

### [Concept 7]

The cleaning member attaching part according to any one of concepts 1 to 6, wherein

a pitch width between the cleaning liquid supply holes along a longitudinal direction in the second region is smaller than a pitch width between the cleaning liquid supply holes along a longitudinal direction in the first region.

### [Concept 8]

The cleaning member attaching part according to any one of concepts 1 to 7, wherein

a plurality of cleaning liquid supply holes are provided at a same position along a longitudinal direction in a second region, and

the number of the cleaning liquid supply holes at the same position along the longitudinal direction in the second region is larger than the number of the cleaning liquid supply holes at a same position along the longitudinal direction in the first region.

### [Concept 9]

The cleaning member attaching part according to concept 8, wherein

the cleaning liquid supply holes at the same position along the longitudinal direction in the second region are arranged at intervals of approximately 90 degrees when viewed along an axial direction, and

the cleaning liquid supply holes at the same position along the longitudinal direction in the first region are arranged at intervals of approximately 180 degrees when viewed along the axial direction.

### [Concept 10]

A cleaning member assembly comprising:

the cleaning member attaching part according to any one of concepts 1 to 9; and

a cleaning member provided on a surface of the cleaning member attaching part.

### [Concept 11]

A substrate cleaning apparatus comprising:

a substrate support part to hold a substrate;

a cleaning member assembly having a cleaning member attaching part according to any one of concepts 1 to 9 and a cleaning member provided on a surface of the cleaning member attaching part; and

a cleaning member holding part that holds the cleaning member assembly.

### [Concept 12]

A cleaning member assembly comprising:

a unit main body; and

a plurality of nodules that projects outward from the unit main body, wherein

the unit main body has:
a gap that extends therein; and
a plurality of cleaning liquid supply holes that communicates with the gap and discharges cleaning liquid toward the unit main body or the nodules,

the gap is configured such that the cleaning liquid flows in from a first end part side, and

an area proportion of the cleaning liquid supply holes in a second region on a second end part side opposite to a first end part to a surface of the main body is larger than an area proportion of the cleaning liquid supply holes in a first region on the first end part side to the surface of the main body.

### [Concept 13]

13. The cleaning member assembly according to claim 12, wherein the nodules are formed by being molded on the unit main body.

In the present invention, in a case of adopting an aspect in which the area proportion of the cleaning liquid supply holes to the second region in the surface of the main body is larger than the area proportion of the cleaning liquid supply holes in the first region located near the first end part side to the surface of the main body, it is possible to suppress variations in the discharge amount of the cleaning liquid from the cleaning member. It is also possible to prevent the supplied cleaning liquid such as inner rinse from flowing out to a driven part side.

### BRIEF DESCRIPTION OF DRAWINGS

FIG. 1 is a perspective view of an example of a cleaning member holding part that can be used in a first embodiment of the present invention;

FIG. 2 is a perspective view of a substrate cleaning apparatus that can be used in the first embodiment of the present invention;

FIG. 3 is a perspective view of a cleaning member assembly that can be used in the first embodiment of the present invention;

FIG. 4 is a side sectional view of an example of a cleaning member assembly that can be used in the first embodiment of the present invention;

FIG. 5 is a side sectional view of another example of a cleaning member assembly that can be used in the first embodiment of the present invention;

FIG. 6 is a side sectional view of an example of a cleaning member attaching part that can be used in the first embodiment of the present invention;

FIG. 7 is a side sectional view of another example of a cleaning member attaching part that can be used in the first embodiment of the present invention;

FIG. 8(a) is a diagram showing a tray and others used in an example of the first embodiment of the present invention, and FIG. 8(b) is a side sectional view of a cleaning member assembly used in the embodiment of the first embodiment;

FIG. 9(a) is a graph showing experimental results at a supply rate of 450 ml/mm in the example of the first embodiment of the present invention, and FIG. 9(b) is a graph showing experimental results of the first embodiment of the present invention at a supply rate of 800 ml/mm in the example of the embodiment;

FIG. 10(a) is a graph showing experimental results in first comparative example, and FIG. 10(b) is a graph showing experimental results in second comparative example;

FIG. 11 is a schematic plan view showing the overall configuration of a substrate processing apparatus according to the first embodiment of the present invention;

FIG. 12 is a side sectional view of another example of a cleaning member assembly that can be used in a second embodiment of the present invention;

FIG. 13(a) is a side sectional view of another example of a cleaning member attaching part that can be used in a third embodiment of the present invention, FIG. 13(b) is a lateral cross-sectional view of the cleaning member attaching part taken along a straight line B-B of FIG. 13(a), and FIG. 13(c) is a lateral cross-sectional view of the cleaning member attaching part taken along a straight line C-C of FIG. 13(a);

FIG. 14 is a side sectional view of a modification example of a cleaning member assembly that can be used in the embodiments of the present invention;

FIG. 15 is a side sectional view of another modification example of a cleaning member assembly that can be used in the embodiments of the present invention;

FIG. 16 is a side sectional view of still another modification example of a cleaning member assembly that can be used in the embodiments of the present invention;

FIG. 17 is a diagram for describing an example of a method of manufacturing an integrally molded cleaning member that can be used in the embodiments of the present invention; and

FIG. 18 is a side sectional view of further still another modification example of a cleaning member assembly that can be used in the embodiments of the present invention.

### DETAILED DESCRIPTION

### First Embodiment

### <<Configuration>>

A first embodiment of a substrate processing apparatus including a substrate cleaning apparatus and the like will be described.

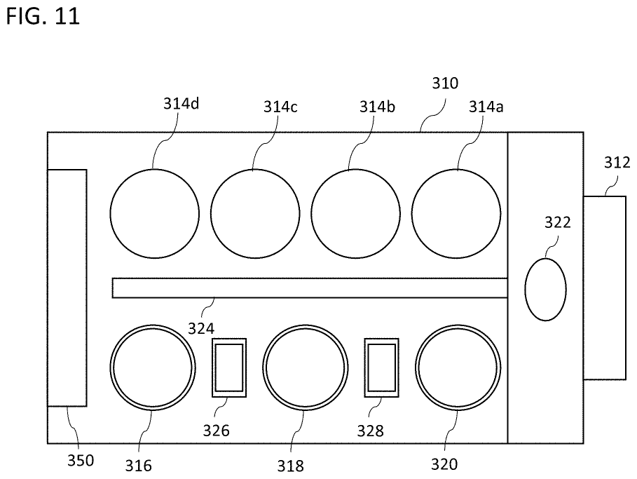

As shown in FIG. 11, the substrate processing apparatus, according to the present embodiment, has a roughly rectangular housing 310 and a load port 312; a substrate cassette that stocks a number of substrates W is put on the load port 312. The load port 312 is placed adjacent to the housing 310. The load port 312 can be loaded with an open cassette, a SMIF (Standard Mechanical Interface) pod or a FOUP (Front Opening Unified Pod). A SMIF pod and a FOUP are hermetically sealed enclosure that stores therein a substrate cassette and covers it with a bulkhead, and whereby an environment independent of the external space can be maintained. The substrate W is, for example, a semiconductor wafer and the like.

Inside the housing 310, a plurality of (in an aspect shown in FIG. 11, four) polishing units 314a to 314d, first and second cleaning units 316 and 318 for cleaning a polished substrate W, and a drying unit 320 for drying the cleaned substrate W is contained. The polishing units 314a to 314d are arranged along a long side of the substrate processing apparatus, and the cleaning units 316 and 318 and the drying unit 320 are also arranged along the long side of the substrate processing apparatus. The substrate processing apparatus according to the present embodiment can polish various substrates W in a step of manufacturing a semiconductor wafer with a diameter of 300 mm or 450 mm, a flat panel, an image sensor such as complementary metal oxide semiconductor (CMOS) or charge coupled device (CCD), and a magnetic film in a magnetoresistive random access memory (MRAM). The substrate processing apparatus according to other embodiment may be configured to clean and dry a substrate W without a polishing unit for polishing the substrate W inside the housing 310.

In an area surrounded by the load port 312, and the polishing unit 314a and the drying unit 320 that are located on the side of the load port 312, a first transfer robot 322 is placed. Furthermore, a conveyance unit 324 is placed parallel to the polishing units 314a to 314d as well as the cleaning units 316 and 318 and the drying unit 320. The first transfer robot 322 receives a pre-polished substrate W from the load port 312 and transfers the substrate W to the conveyance unit 324, or receives a dried substrate W, which is removed from the drying unit 320, from the conveyance unit 324.

A second transfer robot 326 for transferring a substrate W between the first cleaning unit 316 and the second cleaning unit 318 is placed between the first cleaning unit 316 and the second cleaning unit 318, and a third conveyance unit 328 for transferring the substrate W between the second cleaning unit 318 and the drying unit 320 is placed between the second cleaning unit 318 and the drying unit 320. Furthermore, inside the housing 310, an overall control unit 350, which is included in a control unit, for controlling the operation of each device of the substrate processing apparatus is placed. In the present embodiment, there is described the aspect in which the overall control unit 350 is placed inside the housing 310; however, the placement of the control unit 50 is not limited to this, and the overall control unit 350 may be placed outside the housing 310, and the overall control unit 350 may be provided at a remote place.

A roll cleaning apparatus for scrubbing a surface of a substrate W while rotating around the center axis parallel with the substrate W by bringing the roll cleaning members 90 linearly extending almost along the full diameter of the substrate W into contact with cleaning liquid may be used for the first cleaning unit 316. A pencil cleaning apparatus for scrubbing a surface of a substrate W by bringing the contact faces of the vertically-extending columnar pencil cleaning members 90 into contact with cleaning liquid and moving the pencil cleaning members 90 in one direction while rotating may be used for the second cleaning unit 318. A spin drying unit for drying a substrate W by injecting IPA steam from a moving injection nozzle toward the horizontally-held and rotating substrate W and drying the substrate W by centrifugal force by faster rotating the substrate W may be used for the drying unit 320.

The first cleaning unit 316 may use not a roll cleaning apparatus, but a pencil cleaning apparatus similar to the second cleaning unit 318 or a two-fluid jet cleaning apparatus for cleaning a surface of a substrate W by two-fluid jet. Further, the second cleaning unit 318 may use not a pencil cleaning apparatus, but a roll cleaning apparatus similar to the first cleaning unit 316, or a two-fluid jet cleaning apparatus for cleaning a surface of a substrate W by two-fluid jet.

The cleaning liquid in the present embodiment contains rinse liquid, such as deionized water (DIW), and chemical liquid, such as ammonia hydrogen peroxide (SC1), hydrochloric acid hydrogen peroxide (SC2), sulfuric acid hydrogen peroxide (SPM), sulfuric acid hydrolysate, or hydrofluoric acid. In the present embodiment, unless otherwise specified, cleaning liquid means either rinse liquid, chemical liquid or the both rinse liquid and chemical liquid.

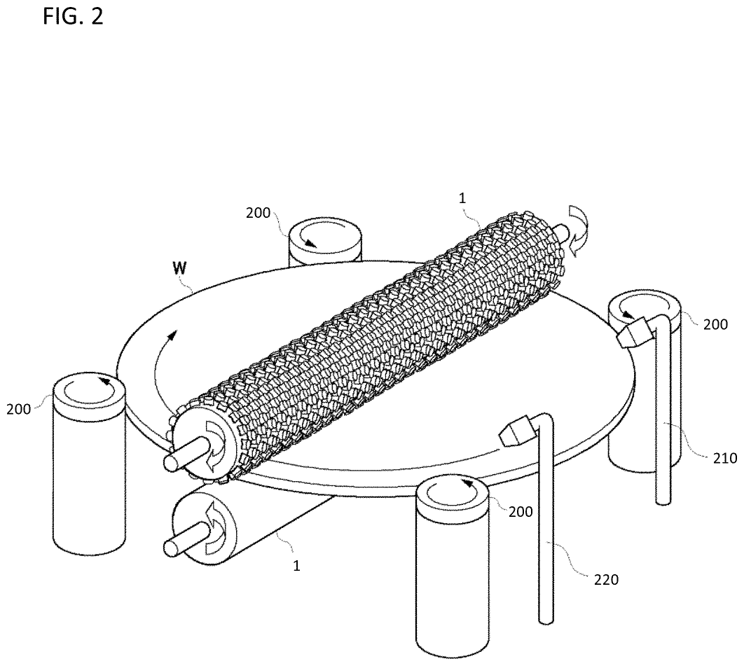

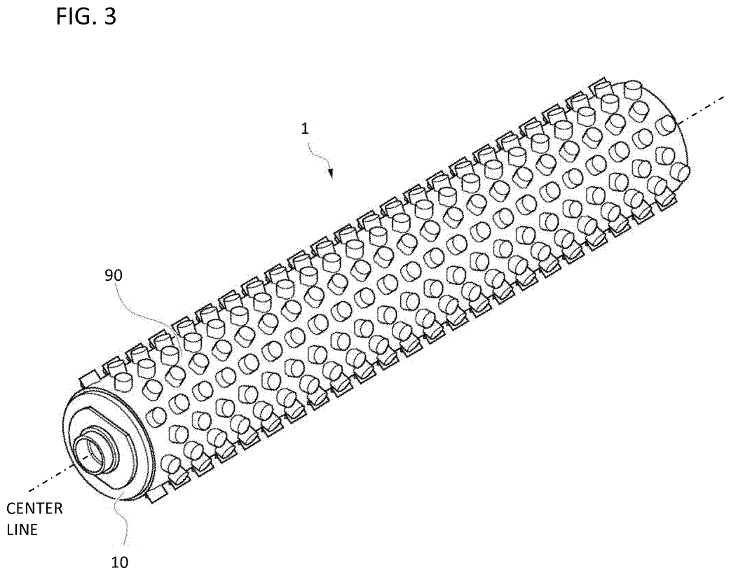

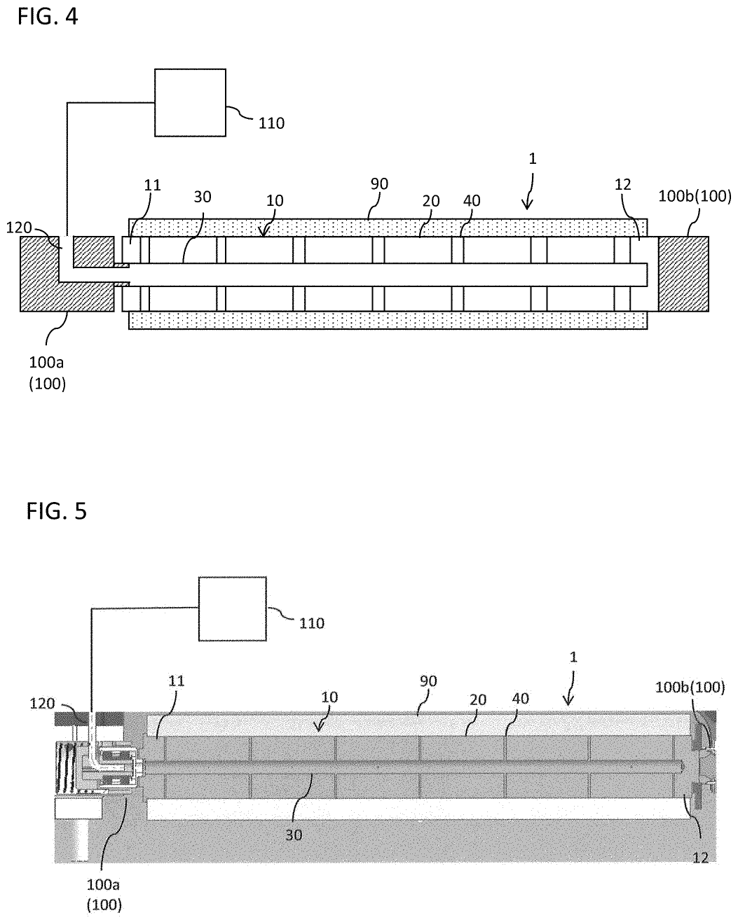

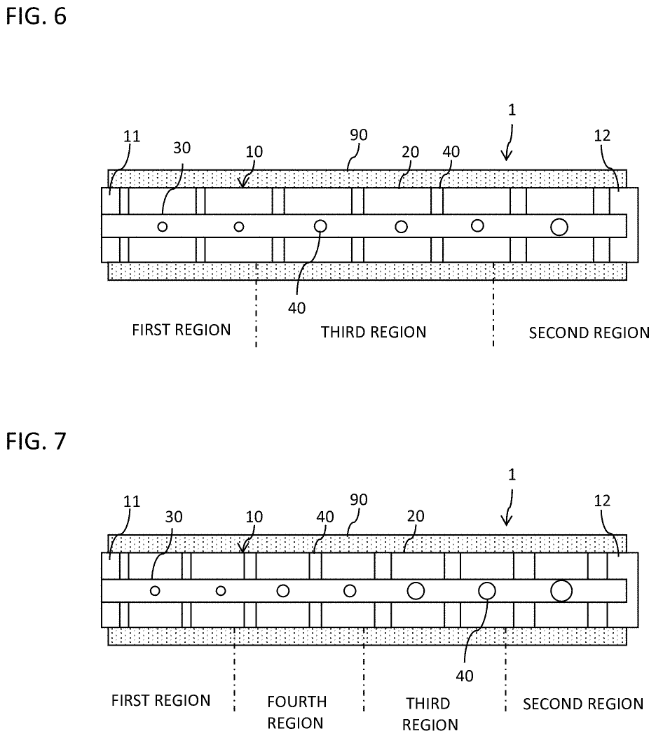

As shown in FIGS. 4 and 5, the substrate cleaning apparatus according to the present embodiment may have a cleaning member holding part 100 that has a bearing capable of rotatably holding a cleaning member assembly 1 for cleaning a substrate W, and a supply unit 110 that supplies cleaning liquid to the cleaning member assembly 1. The cleaning liquid is typically inner rinse liquid, for example, pure water. However, the present invention is not limited to such an aspect, and a chemical liquid may be used. As shown in FIG. 2, the substrate cleaning apparatus may have a substrate support part 200 that holds the substrate W. The substrate support part 200 may hold the substrate W so as to extend in the horizontal direction, may hold the substrate W so as to extend in the vertical direction, or may hold the substrate W while being inclined from the horizontal direction. The substrate support part 200 may rotate while holding the substrate W by chucking or suctioning, or may support the substrate W while rotating the substrate W like a spindle shown in FIG. 2. A chemical liquid supply unit 210 for supplying a chemical liquid to the substrate W and a rinse liquid supply unit 220 for supplying a rinse liquid to the substrate W may be provided. FIGS. 4 and 5 are side sectional views of the cleaning member assembly, which show cross sections of the cleaning member assembly passing through a center line of a cleaning member attaching part 10 (see FIG. 3) and taken at a part where no modules are provided. FIGS. 6, 7, 8(b), 12, and 13(a) described later illustrate cross sections of the cleaning member assembly passing through the center line of the cleaning member attaching part 10 and taken at a part where no nodules are provided. The center line shown in FIG. 3 matches a rotation axis of the cleaning member assembly 1 shown in FIG. 2.

Cleaning liquid such as inner rinse liquid may be supplied in a range of 400 ml/mm to 1000 ml/mm. The cleaning member assembly 1 may be rotated by the cleaning member holding part 100 at a rotation speed of 50 rpm to 300 rpm.

As shown in FIG. 3, the cleaning member assembly 1 may have a cleaning member attaching part 10 and a cleaning member 90 attached on a surface of the cleaning member attaching part 10. In an example described below, a roll cleaning member 90 is used as the cleaning member 90. The roll cleaning member 90 may be made of a sponge with nodules 95 having a plurality of protrusion members. In general, when the cumulative usage time of the roll cleaning member 90 is long, the influence of pressing force and frictional force received during the substrate cleaning is accumulated in the cleaning member, so that the cleaning member tends to deform and decrease in elastic force. Therefore, in one embodiment, the thickness of the roll cleaning member is set to 45% or less of a maximum radius of the cleaning member attaching part 10, and the protrusion height of the nodules 95 is set to 5% to 25% of the maximum radius of the cleaning member attaching part 10. This makes it possible to suppress an obvious decrease in the elastic force of the cleaning member due to an increase in the cumulative usage time (the maximum radius of the cleaning member attaching part refers to a distance from a longitudinal axial center of the cleaning member attaching part to tops of the nodules 95). In one embodiment, in a state where the roll cleaning member 90 is attached on the cleaning member attaching part 10, setting the protrusion height of the nodules 95 to 5% to 25% or less of the maximum radius of the roll cleaning member 90 makes it possible to further suppress an obvious decrease in the elastic force of the cleaning member due to an increase in the cumulative usage time.

In one embodiment, the area of the top of each of the nodules 95 can be 5 μcm² or less.

In one embodiment, the cleaning member attaching part 10 can be PVDF or PTFE.

The cleaning member assembly 1 may have one end held by the cleaning member holding part 100 in a following manner and the other end driven by a driving unit (not shown) with a motor. That is, the cleaning member holding part 100 may have a second cleaning member holding part 100b driven by the driving unit and a first cleaning member holding part 100a held in the following manner (see FIGS. 4 and 5).

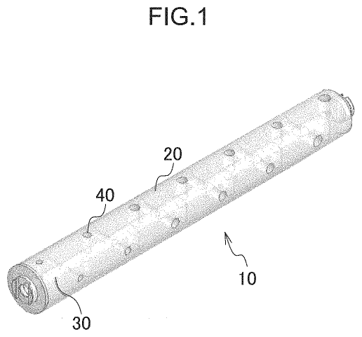

As shown in FIG. 1, the cleaning member attaching part 10 may have a main body 20, a cleaning liquid introduction part (gap) 30 extending inside the main body 20, and a plurality of cleaning liquid supply holes 40 communicating with the cleaning liquid introduction part 30. The cleaning member attaching part 10 may be formed in a cylindrical shape having a hollow region. This hollow region may constitute the cleaning liquid introduction part 30, and the cleaning liquid supply holes 40 may communicate with the cleaning liquid introduction part 30, so that the cleaning liquid supplied to the cleaning liquid introduction part 30 soaks into the cleaning member 90 and is used to clean the substrate W.

As shown in FIGS. 4 and 5, the cleaning liquid to the cleaning liquid introduction part 30 may be introduced via a supply pipe 120 provided inside the first cleaning member holding part 100a. In this case, the cleaning liquid flows into the cleaning liquid introduction part 30 from a first end part 11 side that is the one end part held in the following manner. Referring to FIGS. 4 and 5, unlike the aspect shown in FIG. 1, there are provided only the cleaning liquid supply holes 40 extending in the vertical direction in FIGS. 4 and 5.

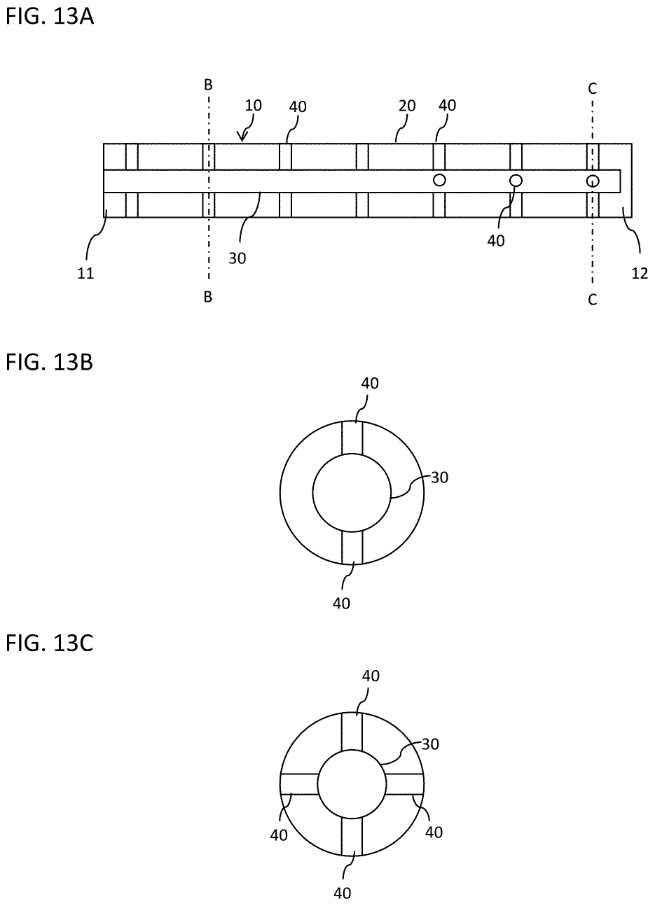

The area proportion of the cleaning liquid supply holes 40 in a second region on a second end part 12 side opposite to the first end part 11 side to the surface of the main body 20 may be larger than the area proportion of the cleaning liquid supply holes 40 in the first region on the first end part 11 to the surface of the main body 20 (see FIGS. 6 and 7). In other words, when hole area proportion/unit area of the first end part 11 side is compared with hole area proportion/unit area of the second end part 12 side by the same longitudinal distance, it can be said that the hole area proportion/unit area of the first end part 11 side is larger than the hole area proportion/unit area of the second end part 12 side. Referring to FIGS. 6 and 7, as in the aspect shown in FIG. 1, there are provided the cleaning liquid supply holes 40 extending in the vertical direction of FIGS. 6 and 7 and the cleaning liquid supply holes 40 extending in a normal direction of the paper surface of FIGS. 6 and 7. Out of the cleaning liquid supply holes 40 extending in the normal direction of the paper surface, FIGS. 6 and 7 show the cleaning liquid supply holes 40 positioned at the back side of the paper surface (see FIGS. 13(a) and 13(c)).

In the present embodiment, the area proportion of the cleaning liquid supply holes 40 to the surface of the main body 20 is also called “supply hole area proportion”. When the cleaning member attaching part 10 is divided into regions along the longitudinal direction (axial direction) based on the supply hole area proportion, the region located closest to the first end part 11 side and having the same supply hole area proportion will be called first region, and the region located closest to the second end part 12 side and having the same supply hole area proportion will be called second region.

The supply hole area proportion is determined by dividing the area of the cleaning liquid supply holes 40 in the surface of the main body 20 by the surface area of the main body 20 with the assumption that the main body 20 does not have the cleaning liquid supply holes 40. That is, the supply hole area proportion of the first region is calculated as s1/S1 where the surface area of the main body 20 on the assumption that the cleaning liquid supply holes 40 do not exist in the first region is S1 and the total area of the cleaning liquid supply holes 40 in the surface of the main body 20 in the first region is s1, and the supply hole area proportion of the second region is calculated as s2/S2 where the surface area of the main body 20 on the assumption that the cleaning liquid supply holes 40 do not exist in the second region is S2 and the total area of the cleaning liquid supply holes 40 in the surface of the main body 20 in the second region is s2. Then, there is a relationship of s1/S1<s2/S2.

The cross-sectional area of the cleaning liquid supply holes 40 in the second region may be larger than the cross-sectional area of the cleaning liquid supply hole 40 in the first region. The cross-sectional area of the cleaning liquid supply holes 40 means an area in a cross section orthogonal to a direction in which the cleaning liquid supply holes 40 extend (a radial direction of the cleaning member attaching part 10). The cross-sectional area of the cleaning liquid supply holes 40 may have a cylindrical shape with a constant value in the direction in which the cleaning liquid supply holes 40 extend (the radial direction of the cleaning member attaching part 10). Otherwise, the cross-sectional area of the cleaning liquid supply holes 40 may have a truncated cone shape with changes in the direction in which the cleaning liquid supply holes 40 extend, for example. The cross-sectional area on the outer side may be larger than the cross-sectional area on the inner side, or in reverse, the cross-sectional area on the inner side may be larger than the cross-sectional area on the outer side. In a case where the cross-sectional area of the cleaning liquid supply holes 40 changes in the direction in which the cleaning liquid supply holes 40 extend, in the present embodiment, the cross-sectional area of the cleaning liquid supply holes 40 in the second region is larger than the cross-sectional area of the cleaning liquid supply holes 40 in the first region when these cross-sectional areas are compared with each other at the same position in the direction in which the cleaning liquid supply holes 40 extend (the radial direction).

The present embodiment may be in an aspect in which only the first region and the second region are provided. However, the present embodiment is not limited to this but a third region, a fourth region, . . . , and an n-th region (“n” denotes an integer of 3 or more) may be provided. The diameter of the cleaning liquid supply holes 40 in each of the regions may be in a range of 4 mm or more to 11 mm or less, and more specifically, the diameter of the cleaning liquid supply holes 40 in each of the regions may be in a range of 5 mm or more to 10 mm or less. The largest-diameter cleaning liquid supply hole 40 may have a diameter that is 1.5 times or more to 2.5 times or less the diameter of the smallest-diameter cleaning liquid supply hole 40. More specifically, the largest-diameter cleaning liquid supply hole 40 has a diameter that is 1.7 times or more to 2.0 times or less the diameter of the smallest-diameter cleaning liquid supply hole 40. The diameter of the cleaning liquid supply holes 40 in the conventional cleaning member attaching part is about 1 mm. Thus, setting the diameter of the cleaning liquid supply hole 40 to 5 mm or more means a significant increase of the diameter.

The diameter of the cleaning liquid introduction part 30 may be 8 mm or more to 11 mm or less. The diameter of the cleaning liquid introduction part 30 in the conventional cleaning member attaching part is about 7 mm. Thus, setting the diameter of the cleaning liquid introduction part 30 to 8 mm or more means an increase of the diameter.

As an example, as shown in FIG. 6, a third region may be provided between the first region and the second region. In this aspect, the area proportion of the cleaning liquid supply holes 40 (supply hole area proportion) in the third region to the surface of the main body 20 may be larger than the area proportion of the cleaning liquid supply holes 40 (supply hole area proportion) in the first region to the surface of the main body 20 and may be smaller than the area proportion of the cleaning liquid supply holes 40 (supply hole area proportion) in the second region to the surface of the main body 20.

As another example, as shown in FIG. 7, a fourth region may be provided between the third region and the first region. In this aspect, the area proportion of the cleaning liquid supply holes 40 (supply hole area proportion) in the fourth region to the surface of the main body 20 may be larger than the area proportion of the cleaning liquid supply holes 40 (supply hole area proportion) in the first region to the surface of the main body 20 and may be smaller than the area proportion of the cleaning liquid supply holes 40 (supply hole area proportion) in the third region to the surface of the main body 20.

The cross-sectional area of the cleaning liquid supply holes 40 in the fourth region may be larger than the cross-sectional area of the cleaning liquid supply hole 40 in the first region. In addition, the cross-sectional area of the cleaning liquid supply holes 40 in the third region may be larger than the cross-sectional area of the cleaning liquid supply holes 40 in the fourth region, and may be smaller than the cross-sectional area of the cleaning liquid supply holes 40 in the second region.

When the third region or more are provided, an n-th region with the largest number is provided adjacent to the first region, the third region with the smallest number is provided adjacent to the second region, and the third region to the n-th region are provided in ascending numeric order. As described above, the region is divided along the longitudinal direction of the cleaning member attaching part 10 based on the supply hole area proportion, and thus the supply hole area proportion differs among the regions. In an aspect in which the supply hole area proportion is smaller on the first end part 11 side and the supply hole area proportion is larger on the second end part 12 side, the supply hole area proportion is smallest in the first region, the supply hole area proportion in the n-th region is second smallest, the supply hole area proportion in an n−1-th region is third smallest, . . . , the supply hole area proportion in the fourth region is the third largest, the supply hole area proportion in the third region is the second largest, and the supply hole area proportion in the second region is the largest.

The boundary between the regions is formed along the surface direction with the axial direction as the normal direction (along the radial direction of the cleaning member attaching part 10) at an intermediate point between the cleaning liquid supply holes 40 constituting different supply hole area proportions. When the cross-sectional area of the cleaning liquid supply holes 40 varies as in this aspect, a boundary between the regions is formed at the middle point between the cleaning liquid supply holes 40 having different cross-sectional areas when viewed along the axial direction (the cleaning liquid supply holes 40 located at the ends of the regions). For example, in the aspect shown in FIG. 6, a boundary between the first region and the third region is located at an intermediate point between the fourth cleaning liquid supply hole 40 and the fifth cleaning liquid supply hole 40 from the left side, and a boundary between the third region and the fourth region is located at an intermediate point between the tenth cleaning liquid supply hole 40 and the eleventh cleaning liquid supply hole 40 from the left side.

The cross-sectional area of the cleaning liquid introduction part 30 extending inside the main body 20 may correspond to the cross-sectional area of the cleaning liquid supply holes 40 in the second region having the largest cross-sectional area. In the present application, the term “correspond” means that the difference between the two falls within a range of 5% on the basis of a large value, and that, if Sa≤Sb, 0.95×Sb≤Sa≤Sb, and if Sa>Sb, Sa>Sb≥0.95×Sa where Sa represents the cross-sectional area of the cleaning liquid introduction part 30 and Sb represents the cross-sectional area of the cleaning liquid supply holes 40 in the second region.

As shown in FIG. 1, the cleaning liquid supply holes 40 may be provided in pairs at an angle of 180 degrees therebetween when viewed along the axial direction (the longitudinal direction of the cleaning member 90) such that the two cleaning liquid supply holes 40 are linearly provided. In addition, the pair of cleaning liquid supply holes 40 adjacent in the axial direction may be positioned at angles different from each other by approximately 90 degrees when viewed along the axial direction. Providing linearly the two cleaning liquid supply holes 40 makes it easy to form the cleaning liquid supply holes 40. In addition, providing the cleaning liquid supply holes 40 at angles different from each other by approximately 90 degrees when viewed along the axial direction makes it possible to supply the cleaning liquid to the cleaning member 90 through the cleaning liquid supply holes 40 in a well-balanced manner. However, this arrangement of the cleaning liquid supply holes 40 is merely an example, and the cleaning liquid supply holes 40 may be arranged at various angles when viewed along the axial direction (the longitudinal direction of the cleaning member 90). Further, the cleaning liquid supply holes 40 adjacent to each other in the axial direction may be in various positional relationship.

When the cleaning member attaching part 10 is considered as a manifold, the branch flow rate in the manifold is determined by the pressure distribution in the manifold. The static pressure tends to increase for each of the branches (each of the cleaning liquid supply holes 40), and the flow rate tends to increase accordingly. However, the tendency differs depending on the loss ratio (loss ratio=(cross-sectional area of manifold/total branch pipe area)²). In the cleaning member attaching part 10 used in the present embodiment, the loss ratio is typically 1 or less, the flow rate tends to increase with increasing proximity to the second end part 12 side. As shown in the following equation, an increase in the flow rate under the same cross-sectional area condition means that the flow velocity is high=the pressure is high.

Q (flow rate)=C (discharge coefficient)×A (cross-sectional area)×V (flow velocity)=C×A×(2×P (pressure)/ρ (fluid density))^{0.5}

From the above, it is conceivable to adopt the following aspect in order to make the flow rate close to a constant value in the longitudinal direction.

1. Reduce the flow velocity at the second end part 12 side=lower the pressure

2. Expand the diameter of the cleaning member attaching part 10

3. Restrict the cleaning liquid supply holes 40 and change the individual hole diameters according to the pressure distribution

4. Make the cleaning member attaching part 10 as a tapered pipe to uniform the flow rate of the main pipe

Of the aspects “1” to “4”, “1” and “2” are employed in the present embodiment. However, the present invention is not limited to this but the aspects “3” and “4” can be adopted.

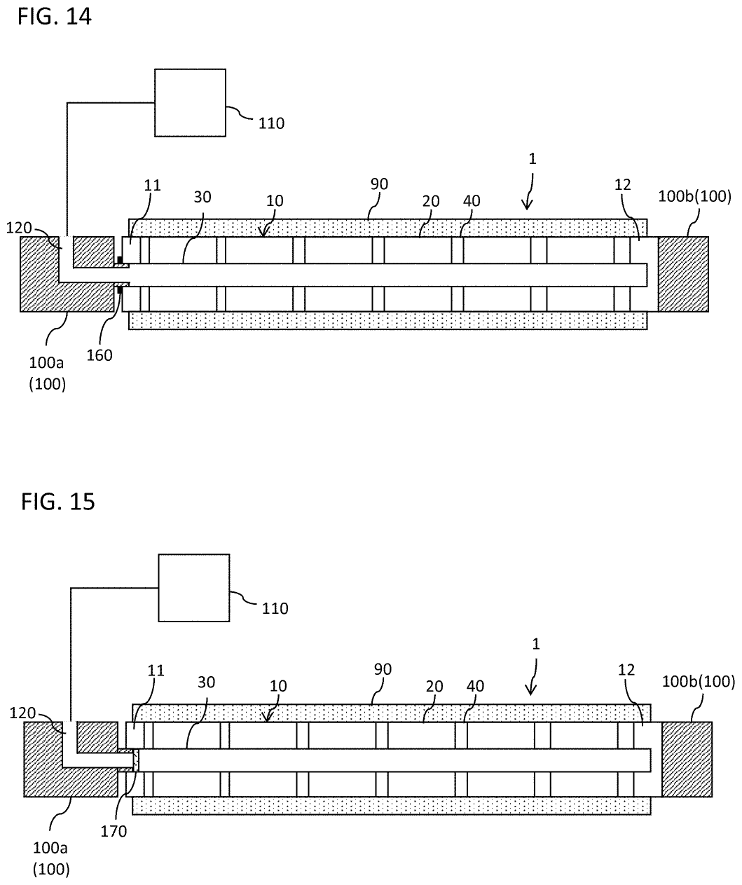

In order to prevent backflow at the first cleaning member holding part 100a (root end part), after attachment of the cleaning member attaching part 10 to the first cleaning member holding part 100a, the cleaning member attaching part 10 may be covered with a sealing member 160 to have sealing properties (see FIG. 14). Alternatively, the sealing member 160 (such as an O-ring) may be provided directly on a sliding part where the cleaning member attaching part 10 and the cleaning member 90 are in contact with each other to improve the sealing properties (not shown). Further, a check valve 170 may be provided at an inflow port of the cleaning member attaching part 10 (see FIG. 15).

Further, a difference may be provided between a porosity of the cleaning member 90 on the second end part 12 side (tip part) and a porosity of the cleaning member 90 on the first end part 11 side (root end part). Typically, when a sponge is used as the cleaning member 90, the porosity of the cleaning member 90 on the second end part 12 side (tip part) is higher than the porosity of the cleaning member 90 on the first end part 11 side (root end part). For example, the porosity of the cleaning member 90 on the second end part 12 side (tip part) can be 90%, and the porosity of the cleaning member 90 on the first end part 11 side (root end part) can be 80%.

The porosity can be defined as in the following equation:

Porosity (%)=(apparent volume−true volume)/(apparent volume)×100

Actually, the porosity can be obtained by sufficiently drying a target member with a dryer, measuring a density with a dry automatic densimeter, and calculating the apparent volume and the true volume from the density.

When the porosity is 80% or less, the cleaning member is likely to bend, and when the porosity is 98% or more, the strength required for cleaning the substrate cannot be secured and the cleaning property is lowered unfavorably.

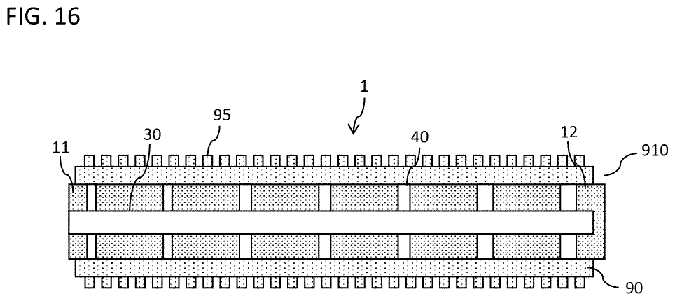

As shown in FIG. 16, in the cleaning member assembly 1, the cleaning member attaching part 10 and the cleaning member 90 may be integrally formed, or the cleaning member 90 may be formed on the cleaning member attaching part 10. In this case, a unit main body 910 is constituted by the cleaning member attaching part 10 and the cleaning member 90. The cleaning member assembly 1 may have the column-shaped unit main body 910 and a plurality of nodules 95 projecting outward from the unit main body 910. The unit main body 910 may have the cleaning liquid introduction part 30 extending inside and the plurality of cleaning liquid supply holes 40 communicating with the cleaning liquid introduction part 30. The roll cleaning member 90 may be made of a PVA sponge material. The PVA sponge material can be prepared from a homopolymer of polyvinyl acetate or the like. The material of the roll cleaning member 90 may be nylon, polyurethane, or a combination of polyurethane and PVA, or any other moldable material such as other copolymers that do not scratch the substrate surface but provide material removal suitable for the process.

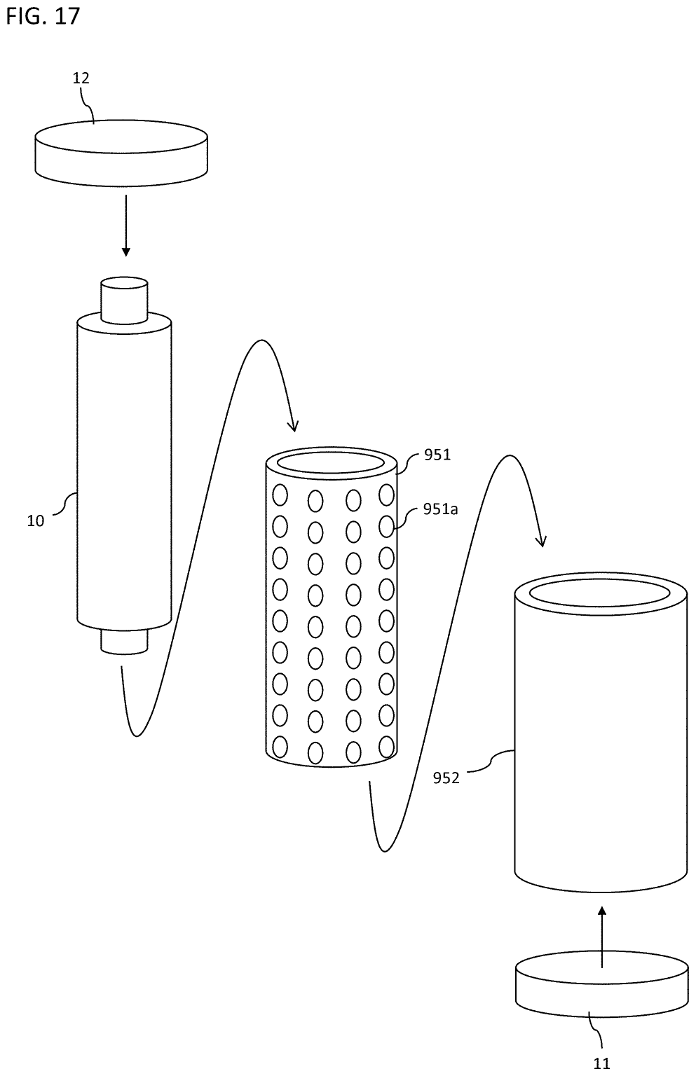

In one embodiment, a mold is formed by a cap member constituting the first end part 11, an inner frame 951 having holes 951a, and an outer frame 952 (see FIG. 17). The cleaning member attaching part 10 is inserted into the inner frame 951 forming the mold. After a filler (for example, wax) is filled in the inside of the cleaning member attaching part 10, and a cap member can be attached to the cleaning member attaching part 10 for capping openings of the cleaning liquid supply holes 40. Next, a PVA material constituting the roll cleaning member 90 is mixed with an aqueous solution containing at least a polyvinyl alcohol having a polymerization degree of 500 to 4000 and a saponification degree of 80% or more, and an aldehyde-based cross-linker, a catalyst, and a starch as a pore-forming agent. The mixed liquid (or foaming solution) is poured between the inner frame 951 and the cleaning member attaching part 10 using a nozzle not shown. Thereafter, the cap member constituting the second end part 12 is attached to the cleaning member attaching part 10, the inner frame 951, and the outer frame 952, and is heated at 40 to 80 degrees to react the liquid. In this way, the elongated cleaning member attaching part 10 having a void extending therein and the porous cleaning layer (PVA porous layer) covering the outer surface of the cleaning member attaching part 10 are integrated with the cleaning member attaching part 10, and a plurality of nodules made of the same porous PVA as the cleaning layer is formed to protrude outward.

Each of the inner frame 951 and the outer frame 952 is openable and closable. Then, the inner frame 951 and the outer frame 952 are opened to remove the cleaning member attaching part 10 from the mold. Then, the filler (for example, wax) filled in the inside of the cleaning member attaching part 10 is removed by a predetermined method, and the cap member that has capped openings of the cleaning liquid supply holes 40 is removed.

Next, the inside of the cleaning member attaching part 10, the openings of the cleaning liquid supply holes 40, and the roll cleaning member 90 are washed with water. By this series of steps, the cleaning member 90 made of a PVA material can be integrally formed (molded) on the cleaning member attaching part 10 while pressing the occurrence of back contamination during use.

In one embodiment, at the manufacture of the cleaning member 90 made of a PVA material on the cleaning member attaching part 10 by integral molding, it is possible to mold the cleaning member made of a PVA material such that the parts of the cleaning member 90 corresponding to the openings of the cleaning liquid supply holes 40 are recessed. With this cleaning member assembly, it is possible to more effectively prevent the cleaning liquid discharged from the cleaning member attaching part 10 to the cleaning member 90 from flowing back inside.

In one embodiment, the cleaning member assembly 1 can allow the cleaning member attaching part 10 and the roll cleaning member 90 to be firmly stuck together with an adhesive.

In one embodiment, the cleaning member assembly 1 is formed such that the inner diameter of the roll cleaning member 90 is smaller than the outer diameter of the cleaning member attaching part 10, and the roll cleaning member 90 is pressed into the cleaning member attaching part 10 so that the cleaning member attaching part 10 and the roll cleaning member 90 are fixedly supported by the elastic force of the roll cleaning member 90. Further, in one embodiment, a surface active agent is applied to the surface of the cleaning member attaching part 10, then the roll cleaning member 90 is inserted into the cleaning member attaching part 10, and then the cleaning member attaching part 10 and the roll cleaning member 90 can be rinsed with water to remove the surface active agent.

In one embodiment, the average pore diameter of the cleaning member 90 can be set to 50 μm to 250 μm (where the average pore diameter is the average of the diameters of a predetermined number of pores randomly extracted from a plurality of pores in the target area). In one embodiment, an apparent density of the cleaning member 90 can be 0.05 g/cm³ or more, and a percentage of water retention can be set to 500% to 1200%. Further, in one embodiment, a 30% compressive stress of the cleaning member 90 in an appropriate water-containing state can be set to 3 kPa or more to 200 kPa or less. The appropriate water-containing state is a weight percentage in the water-containing state with respect to the dry state, and refers to a water-containing state in which the cleaning member 90 has an appropriate elastic force in a substrate cleaning process or the like. In addition, the 30% compressive stress refers to a load per unit area obtained by applying a load to the cleaning member 90 in an appropriate water-containing state from both end surfaces, measuring a load with which the cleaning member 90 is longitudinally 30% crushed by a digital load measuring device, and dividing the measured value by the area of the end surfaces.

### <<Effects>>

Next, advantageous effects of the thus configured present embodiment, which have not yet been described, will be mainly described. Even if it is not described in the Configuration, any configuration described in the Advantageous effects can be adopted in the present invention.

In a case of adopting an aspect in which the area proportion of the cleaning liquid supply holes 40 to the second region in the surface of the main body 20 is larger than the area proportion of the cleaning liquid supply holes 40 in the first region located near the first end part 11 side (see FIGS. 6 and 7) to the surface of the main body 20, it is possible to suppress variations in the discharge amount of the cleaning liquid from the cleaning member 90. It is also possible to prevent the supplied cleaning liquid such as inner rinse from flowing out to a driven part side. As an example, even if the cleaning liquid is supplied at 450 ml/min, the cleaning liquid would flow out to the driven part side in the conventional case, and the amount of the cleaning liquid supplied to the substrate W might be reduced. Adopting the present aspect makes it possible to decrease the amount of the cleaning liquid flowing to the driven part side (eliminate in some cases).

Reducing the amount of the cleaning liquid flowing to the driven part side in this manner makes it possible to bring the amount of the cleaning liquid supplied to the substrate W closer to an accurate value, thereby increasing the cleaning accuracy of the substrate W. In addition, suppressing variations in the discharge amount of the cleaning liquid from the cleaning member 90 makes it possible to increase the cleaning efficiency of the substrate W. Further, efficiently providing the cleaning liquid to the substrate W makes it possible to reduce the necessary amount of the cleaning liquid.

It is also conceivable to adopt an aspect in which a dug portion (recess) is provided on the outer surface of the cleaning member attaching part 10 (the outer edges of the cleaning liquid supply holes 40) to facilitate the outflow of the cleaning liquid. However, it is not preferable to adopt this aspect in that dust is likely to accumulate between the outer surface of the cleaning member attaching part 10 and the inner surface of the cleaning member 90.

In a case where the cross-sectional area of the cleaning liquid supply holes 40 in the second region is larger than the cross-sectional area of the cleaning liquid supply holes 40 in the first region, increasing the cross-sectional area of the cleaning liquid supply holes 40 makes it possible to suppress variations in the discharge amount of the cleaning liquid from the cleaning member 90 and decrease the amount of the cleaning liquid flowing to the driven part side. According to this aspect, it is only necessary to adjust the size of the cleaning liquid supply holes 40, which makes it easy to perform the processing.

In a case of adopting an aspect in which the area proportion of the cleaning liquid supply holes 40 in the third region to the surface of the main body 20 is larger than the area proportion of the cleaning liquid supply holes 40 in the first region to the surface of the main body 20 and is smaller than the area proportion of the cleaning liquid supply holes 40 in the second region to the surface of the main body 20 (see FIG. 6), the region is divided into three or more regions such that the supply hole area proportion can be larger from the first end part 11 (the driven part side) to which the cleaning liquid is to be supplied toward the second end part 12.

In a case of adopting an aspect in which the area proportion of the cleaning liquid supply holes 40 in the fourth region to the surface of the main body 20 is larger than the area proportion of the cleaning liquid supply holes 40 in the first region to the surface of the main body 20 and is smaller than the area proportion of the cleaning liquid supply holes 40 in the third region to the surface of the main body 20 (see FIG. 7), the region is divided into four or more regions such that the supply hole area proportion can be larger from the first end part 11 (the driven part side) to which the cleaning liquid is to be supplied toward the second end part 12.

In a case of adopting an aspect in which the supply hole area proportion is small on the first end part 11 side and the supply hole area proportion is large on the second end part 12 side, the supply hole area proportion in the first region is the smallest, the supply hole area proportion in the n-th region is the second smallest, the supply hole area proportion in the n−1th region is the third smallest, . . . , and in a case of adopting an aspect in which the supply hole area proportion in the third region is the second largest and the supply hole area proportion in the second region is the largest, it is possible to make larger the supply hole area proportion from the first end part 11 to which the cleaning liquid is supplied (the driven part side) toward the second end part 12, accurately suppress variations in the discharge amount of the cleaning liquid from the cleaning member 90, and decrease the amount of the cleaning liquid flowing to the driven part side (eliminate in some cases).

In a case of adopting an aspect in which the cross-sectional area of the cleaning liquid supply holes 40 in the fourth region is larger than the cross-sectional area of the cleaning liquid supply holes 40 in the first region and the cross-sectional area of the cleaning liquid supply holes 40 in the third region is larger than the cross-sectional area of the cleaning liquid supply holes 40 in the fourth region and is smaller than the cross-sectional area of the cleaning liquid supply holes 40 in the second region, adjusting the cross-sectional areas of the cleaning liquid supply holes 40 in the first to fourth regions makes it possible to adjust the supply hole area proportions in these regions.

Setting the cross-sectional area of the cleaning liquid supply holes 40 in the second region located closest to the second end part 12 side corresponding to the cross-sectional area of the cleaning liquid introduction part 30 extending inside the main body 20 makes it possible to more reliably discharge the cleaning liquid having flown into the cleaning liquid introduction part 30 from the cleaning liquid supply holes 40 in the second region, thereby preventing the cleaning liquid from flowing out to the driven part side. That is, setting the cross-sectional area of the cleaning liquid supply holes 40 in the second region corresponding to the cross-sectional area of the cleaning liquid introduction part 30 makes it possible to more reliably discharge the cleaning liquid having flown to the second end part 12 side from the cleaning liquid supply holes 40 in the second region.

The present invention is not limited to the above-described aspect. It is also possible to adopt an aspect in which the supply hole area proportion in a p-th region is not smaller than the supply hole area proportion in a q-th region (“p” and “q” are integers of 2 or larger, and “p” is an integer larger than “q”.) That is, it is possible to adopt an aspect in which the supply hole area proportion in the p-th region the supply hole area proportion in the q-th region, or adopt an aspect in which the cross-sectional area of the cleaning liquid supply holes 40 in the p-th region the cross-sectional area of the cleaning liquid supply holes 40 in the q-th region. As an example, the cross-sectional area of the cleaning liquid supply holes 40 in the fourth region may be equal to or larger than the cross-sectional area of the cleaning liquid supply holes 40 in the third region. In adjusting variations in the discharge amount, this is because it is not necessarily preferable that the supply hole area proportion in the region located near the second end part 12 side is larger than the supply hole area proportion in the second end part 12 side. Therefore, in some cases, an aspect in which the supply hole area proportion in the first region is not the smallest may be adopted so that a region having a supply hole area proportion smaller than the supply hole area proportion in the first region may be provided.

### EXAMPLE

An example according to the present embodiment will be described.

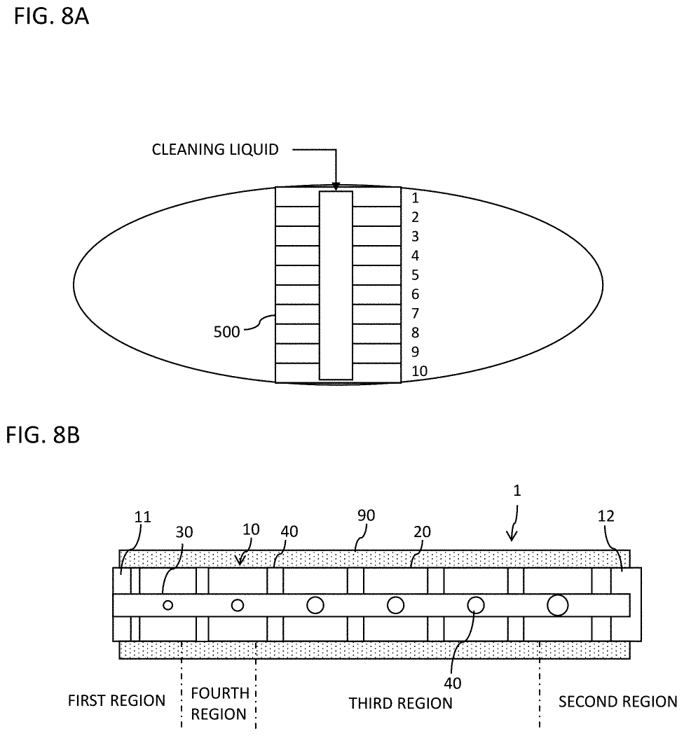

In the example, a tray 500 equally divided into ten parts in the longitudinal direction of the cleaning member 90 made of a sponge (see FIG. 8(a)) was prepared, and the amount of inner rinse collected in each part was measured. Numbers were assigned to the parts in ascending order from “1” on the first end part 11 side to “10” on the second end part 12 side so that the number for the part located closest to the second end part 12 side was “10”.

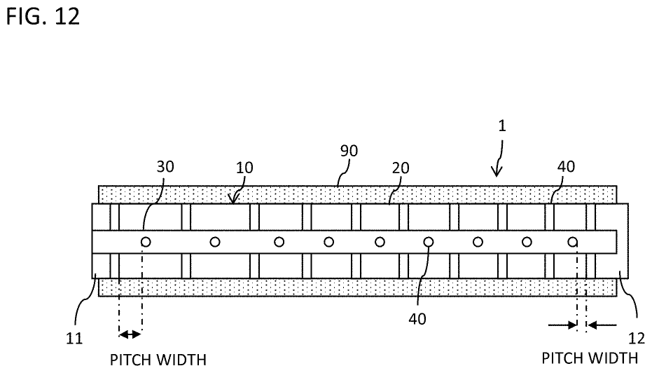

In the example, as shown in FIG. 8(b), the cleaning liquid supply holes 40 were provided at 13 places (the number was 26) along the longitudinal direction of the cleaning member assembly 1. The cleaning liquid supply holes 40 were provided at two places (the number was four) in the first region along the longitudinal direction, provided at two places (the number was four) in the fourth region along the longitudinal direction, provided at seven places (the number was 14) in the third region along the longitudinal direction, and provided at two places (the number was four) in the second region along the longitudinal direction. Each of the cleaning liquid introduction part 30 and the cleaning liquid supply holes 40 located in the main body 20 had a cylindrical shape, the diameter of the cleaning liquid introduction part 30 was 9 mm, and the diameter of the cleaning liquid supply holes 40 in the second region was 9 mm, the diameter of the cleaning liquid supply holes 40 in the third region was 8 mm, the diameter of the cleaning liquid supply holes 40 in the fourth region was 6.5 mm, and the diameter of the cleaning liquid supply holes 40 in the first region was 5 mm. A pitch width (see FIG. 12) between the cleaning liquid supply holes 40 in the example was 24 mm. The longitudinal length of the cleaning member attaching part 10 was 327 mm, and the longitudinal length of the cleaning member 90 was 309 mm.

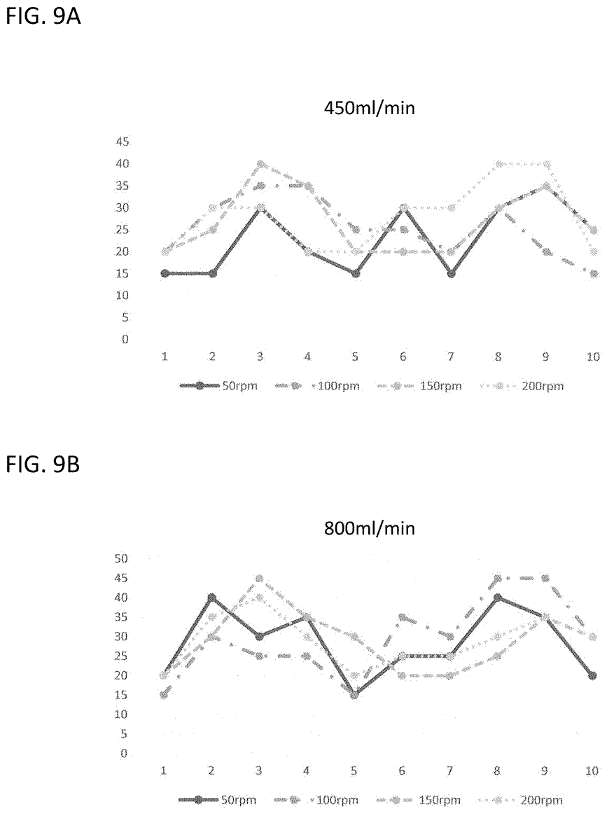

Table 1 below shows results of experiment with the example. In each of cases at the supply rates of 450 ml/min and 800 ml/min and at the rotation speeds of 50 rpm, 100 rpm, 150 rpm, and 200 rpm, there was no place with a discharge amount of 10 mm or less, and the discharge amount at the place with the largest discharge amount was about 2.3 times that at the place with the smallest discharge amount. FIG. 9 shows the results of Table 1 in graph form.

TABLE 1

| Rotation | Supply | | | | | | | | | | | | | | | | |
|---|---|---|---|---|---|---|---|---|---|---|---|---|---|---|---|---|---|
| speed | amount | Sponge part (cleaning member) | | | | | | | | | | | | | | | Supply |
| (rpm) | (ml/min) | 1 | 2 | 3 | 4 | 5 | 6 | 7 | 8 | 9 | 10 | Total | Max. | Min. | Ave. | σ | time |
| 50 | 450 | 15 | 15 | 30 | 20 | 15 | 30 | 15 | 30 | 35 | 25 | 230 | 35 | 15 | 23 | 7.48 | 30 sec |
| 100 | | 20 | 30 | 35 | 35 | 25 | 25 | 20 | 30 | 20 | 15 | 255 | 35 | 15 | 25.5 | 6.50 | |
| 150 | | 20 | 25 | 40 | 35 | 20 | 20 | 20 | 30 | 35 | 25 | 270 | 40 | 20 | 27 | 7.14 | |
| 200 | | 20 | 30 | 30 | 20 | 20 | 30 | 30 | 40 | 40 | 20 | 280 | 40 | 20 | 28 | 7.48 | |
| 50 | 800 | 20 | 40 | 30 | 35 | 15 | 25 | 25 | 40 | 35 | 20 | 285 | 40 | 15 | 28.5 | 8.38 | 15 sec |
| 100 | | 15 | 30 | 25 | 25 | 15 | 35 | 30 | 45 | 45 | 30 | 295 | 45 | 15 | 29.5 | 9.86 | |
| 150 | | 20 | 30 | 45 | 35 | 30 | 20 | 20 | 25 | 35 | 30 | 290 | 45 | 20 | 29 | 7.68 | |
| 200 | | 20 | 35 | 40 | 30 | 20 | 25 | 25 | 30 | 35 | 30 | 290 | 40 | 20 | 29 | 6.24 | |

### COMPARATIVE EXAMPLES

Comparative examples were made in the same aspect as that of the example except that the diameters of the cleaning liquid introduction part 30 and the cleaning liquid supply holes 40 were different.

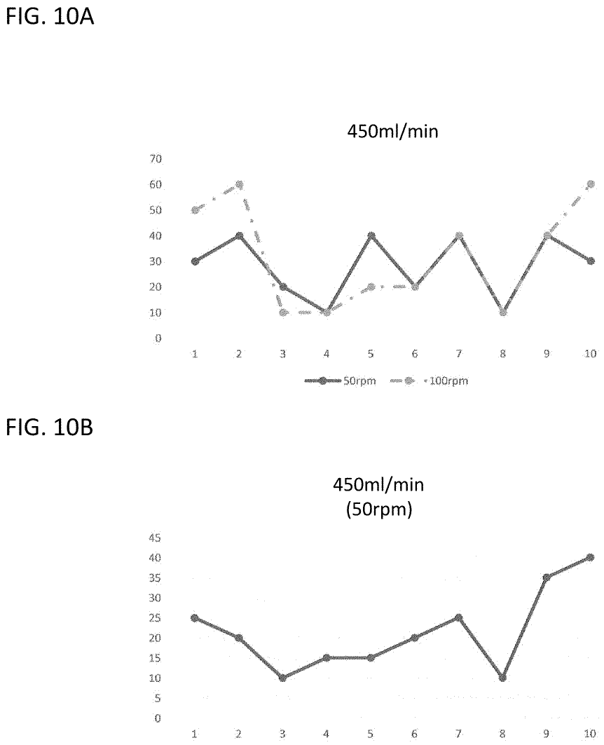

Also in a comparative example 1, the cleaning liquid supply holes 40 were provided at 13 places (the number was 26) along the longitudinal direction of the cleaning member assembly 1 as in the example. In the comparative example 1, each of the cleaning liquid introduction part 30 and the cleaning liquid supply holes 40 located in the main body 20 had a cylindrical shape, the diameter of the cleaning liquid introduction part 30 was 8 mm, and the diameter of the cleaning liquid supply holes 40 was 5 mm. The results of the experiment with the comparative example 1 are as below. There were places with a discharge amount of 10 mm or less, and there also were places with a discharge amount of 60 mm which was the largest and was six times that at the places with the smallest discharge amount. FIG. 10(a) shows the results of Table 2 in graph form.

TABLE 2

| Rotation | Supply | | | | | | | | | | | | | | | | |
|---|---|---|---|---|---|---|---|---|---|---|---|---|---|---|---|---|---|
| speed | amount | Sponge part (cleaning member) | | | | | | | | | | | | | | | Supply |
| (rpm) | (ml/min) | 1 | 2 | 3 | 4 | 5 | 6 | 7 | 8 | 9 | 10 | Total | Max. | Min. | Ave. | σ | time |
| 50 | 450 | 30 | 40 | 20 | 10 | 40 | 20 | 40 | 10 | 40 | 30 | 280 | 40 | 10 | 28 | 11.66 | 30 sec |
| 100 | | 50 | 60 | 10 | 10 | 20 | 20 | 40 | 10 | 40 | 60 | 320 | 60 | 10 | 32 | 19.39 | |

Also in a comparative example 2, the cleaning liquid supply holes 40 were provided at 13 places (the number was 26) along the longitudinal direction of the cleaning member assembly 1 as in the example. In the comparative example 2, each of the cleaning liquid introduction part 30 and the cleaning liquid supply holes 40 located in the main body 20 had a cylindrical shape, the diameter of the cleaning liquid introduction part 30 was 9 mm, and the diameter of the cleaning liquid supply holes 40 was 5 mm. The results of the experiment with the comparative example 2 are as shown below. The comparative example 2 is improved as compared with the comparative example 1. However, there were places with a discharge amount of 10 mm or less, and there also were places with a discharge amount of 40 mm which was the largest and is four times that at the places with the smallest discharge amount. FIG. 10(b) shows the results of Table 3 in graph form.

| Rotation | Supply | | | | | | | | | | | | | | | | |
|---|---|---|---|---|---|---|---|---|---|---|---|---|---|---|---|---|---|
| speed | amount | Sponge part (cleaning member) | | | | | | | | | | | | | | | Supply |
| (rpm) | (ml/min) | 1 | 2 | 3 | 4 | 5 | 6 | 7 | 8 | 9 | 10 | Total | Max. | Min. | Ave. | σ | time |
| 50 | 450 | 25 | 20 | 10 | 15 | 15 | 20 | 25 | 10 | 35 | 40 | 215 | 40 | 10 | 21.5 | 9.50 | 30 sec |

It has also been confirmed that, in a case of adopting an aspect in which the diameter of the cleaning liquid supply holes 40 was 1 mm to 1.2 mm, there was a place in the tray 500 where the cleaning liquid did not flow out of the cleaning member 90.

### Second Embodiment

Next, a second embodiment of the present invention will be described.

As shown in FIG. 12, in the present embodiment, the pitch width between the cleaning liquid supply holes 40 along the longitudinal direction in the second region is smaller than the pitch width between the cleaning liquid supply holes 40 along the longitudinal direction in the first region. In the present embodiment, adopting such an aspect makes the area proportion of the cleaning liquid supply holes 40 (supply hole area proportion) in the second region to the surface of the main body 20 larger than the area proportion of the cleaning liquid supply holes 40 (supply hole area proportion) in the first region located near the first end part 11 side to the surface of the main body 20. Other components are the same as those in the first embodiment, and all the aspects described above in relation to the first embodiment can be adopted. The members described above in relation to the first embodiment will be described using the same reference numerals.

In a case of adjusting the pitch width as in the present embodiment, it is possible to makes the area proportion of the cleaning liquid supply holes 40 in the second region to the surface of the main body 20 larger than the area proportion of the cleaning liquid supply holes 40 in the first region located near the first end part 11 side to the surface of the main body 20 by a simple processing method.

As described that all the aspects described above in relation to the first embodiment can be adopted, three or more regions may be provided in the present embodiment, and the pitch width may be made different among the three or more regions. The longest pitch width may be 1.5 to 2.5 times the shortest pitch width, and more specifically, the longest pitch width may be 1.7 to 2.0 times the shortest pitch width.

The cross-sectional areas of the cleaning liquid supply holes 40 in the present embodiment may have the same size in all the regions. Otherwise, as described above in relation to the first embodiment, the cross-sectional area of the cleaning liquid supply holes 40 may be different in different regions. The cleaning liquid supply holes 40 may have the same cross-sectional area in some of a plurality of different regions (for example, the first region and the fourth region), and the cleaning liquid supply holes 40 may have different cross-sectional areas in the remaining regions (for example, the second region and the third region).

Also in the present embodiment, it is possible to adopt an aspect in which the supply hole area proportion in a p-th region is not smaller than the supply hole area proportion in a q-th region (“p” and “q” are integers of 2 or larger, and “p” is an integer larger than “q”.) That is, it is possible to adopt an aspect in which the supply hole area proportion in the p-th region≥the supply hole area proportion in the q-th region, or adopt an aspect in which the longitudinal pitch width between the cleaning liquid supply holes 40 in the p-th region≤the longitudinal pitch width between the cleaning liquid supply holes 40 in the q-th region.

The supply hole area proportion may be adjusted by combining the pitch width between the cleaning liquid supply holes 40 along the longitudinal direction and the cross-sectional areas of the cleaning liquid supply holes 40. For example, the cross-sectional area of the cleaning liquid supply holes 40 in a r-th region is smaller than the cross-sectional area of the cleaning liquid supply holes 40 in a t-th region, while the pitch width in the r-th region is smaller than the pitch width in the t-th region. As a result, the supply hole area proportion in the r-th region may be larger than the supply hole area proportion in the t-th region (where “r” and “t” are integers).

As a modification example, the pitch width between the cleaning liquid supply holes 40 along the longitudinal direction in the second region is larger than the pitch width between the cleaning liquid supply holes 40 along the longitudinal direction in the first region. In this case, it is possible to adopt an aspect in which the supply hole area proportion in the p-th region≥the supply hole area proportion in the q-th region, or adopt an aspect in which the longitudinal pitch width between the cleaning liquid supply holes 40 in the p-th region≤the longitudinal pitch width between the cleaning liquid supply holes 40 in the q-th region.

### Third Embodiment

Next, a third embodiment of the present invention will be described.

In the present embodiment, a plurality of cleaning liquid supply holes 40 is provided at the same position along the longitudinal direction in a second region, and the number of the cleaning liquid supply holes 40 at the same position along the longitudinal direction in the second region is larger than the number of the cleaning liquid supply holes 40 at the same position along the longitudinal direction in the first region (see FIG. 13). In the present embodiment, adopting such an aspect makes the area proportion of the cleaning liquid supply holes 40 (supply hole area proportion) in the second region to the surface of the main body 20 larger than the area proportion of the cleaning liquid supply holes 40 (supply hole area proportion) in the first region located near the first end part 11 side to the surface of the main body 20. Other components are the same as those in the first or second embodiment, and all the aspects described above in relation to the first or second embodiment can be adopted. The members described above in relation to the first or second embodiment will be described using the same reference numerals.

In a case of adjusting the number of the cleaning liquid supply holes 40 at the same position along the longitudinal direction as in the present embodiment, it is possible to makes the area proportion of the cleaning liquid supply holes 40 in the second region to the surface of the main body 20 larger than the area proportion of the cleaning liquid supply holes 40 in the first region located near the first end part 11 side to the surface of the main body 20 by a simple processing method.

The cleaning liquid supply holes 40 at the same position along the longitudinal direction in the second region may be arranged at intervals of approximately 90 degrees when viewed along the axial direction (see FIG. 13(c)), and the cleaning liquid supply holes 40 at the same position along the longitudinal direction in the first region may be arranged at intervals of approximately 180 degrees when viewed along the axial direction (see FIG. 13(b)). In the present application, “substantially A degrees” means A degrees±3 degrees, and for example, “substantially 90 degrees” means 87 degrees or more to 93 degrees or less.

As described that all the aspects described above in relation to the first embodiment can be adopted, three or more regions may be provided in the present embodiment, and the number of the cleaning liquid supply holes 40 at the same position along the longitudinal direction may be made different among the three or more regions. As an example, in the third region, the cleaning liquid supply holes 40 may be arranged at intervals of approximately 120 degrees when viewed along the axial direction. The largest number of the cleaning liquid supply holes 40 at the same position along the longitudinal direction may be 1.5 times or more to 3.0 times or less the smallest number of the cleaning liquid supply holes 40 at the same position along the longitudinal direction. More specifically, the largest number of the cleaning liquid supply holes 40 at the same position along the longitudinal direction may be 1.8 times or more to 2.5 times or less the smallest number of the cleaning liquid supply holes 40 at the same position along the longitudinal direction.

The number of the cleaning liquid supply holes 40 at the same position along the longitudinal direction in the p-th region may be smaller than the number of the cleaning liquid supply holes 40 at the same position along the longitudinal direction in the q-th region (“p” and “q” are integers of 2 or larger and “p” is an integer greater than “q”). However, the present invention is not limited to this but the number of the cleaning liquid supply holes 40 at the same position along the longitudinal direction in the p-th region may be smaller than the number of the cleaning liquid supply holes 40 at the same position along the longitudinal direction in the q-th region.

The cross-sectional areas of the cleaning liquid supply holes 40 in the present embodiment may have the same size in all the regions. Otherwise, as described above in relation to the first embodiment, the cross-sectional area of the cleaning liquid supply holes 40 may be different in different regions. The cleaning liquid supply holes 40 may have the same cross-sectional area in some of a plurality of different regions (for example, the first region and the fourth region), and the cleaning liquid supply holes 40 may have different cross-sectional areas in the remaining regions (for example, the second region and the third region).

The pitch width between the cleaning liquid supply holes 40 in the present embodiment may have the same length in all the regions. Otherwise, as described above in relation to the second embodiment, the pitch width between the cleaning liquid supply holes 40 may be different in different regions. The cleaning liquid supply holes 40 may have the same pitch width in some of a plurality of different regions (for example, the first region and the fourth region), and the cleaning liquid supply holes 40 may have different pitch widths in the remaining regions (for example, the second region and the third region).

Further, the supply hole area proportion may be adjusted by combining the number of the cleaning liquid supply holes 40 at the same position along the longitudinal direction with one or both of the pitch width between the cleaning liquid supply holes 40 along the longitudinal direction and the cross-sectional area of the cleaning liquid supply holes 40. For example, the cross-sectional area of the cleaning liquid supply holes 40 in a r-th region is smaller than the cross-sectional area of the cleaning liquid supply holes 40 in a t-th region, while the number of the cleaning liquid supply holes 40 at the same position along the longitudinal direction in the r-th region is larger than the number of the cleaning liquid supply holes 40 at the same position along the longitudinal direction in the t-th region. As a result, the supply hole area proportion in the r-th region may be larger than the supply hole area proportion in the t-th region (where “r” and “t” are integers). Further, the pitch width in the r-th region is shorter than the pitch width in the t-th region, while the number of the cleaning liquid supply holes 40 at the same position along the longitudinal direction in the r-th region is smaller than the number of the cleaning liquid supply holes 40 at the same position along the longitudinal direction in the t-th region. As a result, the supply hole area proportion in the r-th region may be smaller than the supply hole area proportion in the t-th region.

As a modification example, the number of the cleaning liquid supply holes 40 at the same position along the longitudinal direction in the second region may be smaller than the number of the cleaning liquid supply holes 40 at the same position along the longitudinal direction in the first region. In this case, the number of the cleaning liquid supply holes 40 at the same position along the longitudinal direction in the p-th region may be larger than the number of the cleaning liquid supply holes 40 at the same position along the longitudinal direction in the q-th region.

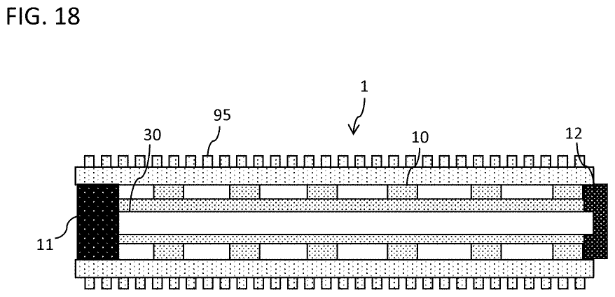

In another embodiment, for example, as shown in FIG. 18, the cleaning member attaching part 10 functioning as a rotation shaft may have irregularities formed on the outer periphery. In this case, the cleaning member attaching part 10 may have the first end part 11 and the second end part 12 in an integral manner.

In one embodiment, the processing object to be cleaned by the cleaning member is not limited to a semiconductor wafer, but may be a silicon wafer, a glass substrate, a printed wiring board, a liquid crystal panel, or a solar panel. Further, the shape of the plane of the processing object may be circular or rectangular, and the thickness of the plane may be a thickness that allows in-plane deflection. Substrates to be processed including a rectangular substrate and a circular substrate include a rectangular substrate and a circular substrate. Further, the rectangular substrate includes a glass substrate, a liquid crystal substrate, a printed circuit board, with a polygonal shape such as a rectangle, and other polygonal plating objects. The circular substrate includes a semiconductor wafer, a glass substrate, and other circular plating objects.

As the cleaning liquid, high-temperature pure water, ammonium hydrogen-peroxide mixture (APM), sulfuric-acid hydrogen peroxide mixture (SPM), carbonated water, and others are applicable.

The description of each embodiments and the disclosure of the drawings described above are merely examples for explaining the invention described in the claims, and the invention described in the claims is not limited by the description of the embodiment or the disclosure of the drawings described above. In addition, the recitation of the claims at the original application is merely an example, and the recitation of the claims can be appropriately changed based on the description of the specification, the drawings, and the like.

### REFERENCE SIGNS LIST

10 Cleaning member attaching part
11 First end part
12 Second end part
20 Main body
30 Cleaning liquid introduction part
40 Cleaning liquid supply hole
90 Cleaning member
100 Cleaning member holding part
200 Substrate support part

What is claimed is:

1. A cleaning member attaching part, on a surface of which a cleaning member is attached, comprising:
a main body;
a cleaning liquid introduction part extending inside the main body; and
a plurality of cleaning liquid supply holes communicating with the cleaning liquid introduction part, wherein
the cleaning liquid introduction part is configured to introduce cleaning liquid from a first end part side, and
an area proportion of the cleaning liquid supply holes in a second region on a second end part side opposite to a first end part to a surface of the main body is larger than an area proportion of the cleaning liquid supply holes in a first region on the first end part side to the surface of the main body.

2. The cleaning member attaching part according to claim 1, wherein
a cross-sectional area of the cleaning liquid supply holes in the second region is larger than a cross-sectional area of the cleaning liquid supply hole in the first region.

3. The cleaning member attaching part according to claim 1, wherein
a third region is provided between the first region and the second region, and
an area proportion of the cleaning liquid supply holes in the third region to the surface of the main body is larger than the area proportion of the cleaning liquid supply holes in the first region to the surface of the main body and is smaller than the area proportion of the cleaning liquid supply holes in the second region to the surface of the main body.

4. The cleaning member attaching part according to claim 3, wherein
a fourth region is provided between the third region and the first region, and
an area proportion of the cleaning liquid supply holes in the fourth region to the surface of the main body is larger than the area proportion of the cleaning liquid supply holes in the first region to the surface of the main body and is smaller than the area proportion of the cleaning liquid supply holes in the third region to the surface of the main body.

5. The cleaning member attaching part according to claim 4, wherein
a cross-sectional area of the cleaning liquid supply holes in the fourth region is larger than a cross-sectional area of the cleaning liquid supply hole in the first region, and
a cross-sectional area of the cleaning liquid supply holes in the third region is larger than the cross-sectional area of the cleaning liquid supply holes in the fourth region and is smaller than a cross-sectional area of the cleaning liquid supply holes in the second region.

6. The cleaning member attaching part according to claim 1, wherein
a cross-sectional area of the cleaning liquid introduction part extending inside the main body corresponds to a cross-sectional area of the cleaning liquid supply holes in the second region.

7. The cleaning member attaching part according to claim 1, wherein
a pitch width between the cleaning liquid supply holes along a longitudinal direction in the second region is smaller than a pitch width between the cleaning liquid supply holes along a longitudinal direction in the first region.

8. The cleaning member attaching part according to claim 1, wherein
a plurality of cleaning liquid supply holes are provided at a same position along a longitudinal direction in a second region, and
the number of the cleaning liquid supply holes at the same position along the longitudinal direction in the second region is larger than the number of the cleaning liquid supply holes at a same position along the longitudinal direction in the first region.

9. The cleaning member attaching part according to claim 8, wherein
the cleaning liquid supply holes at the same position along the longitudinal direction in the second region are arranged at intervals of approximately 90 degrees when viewed along an axial direction, and
the cleaning liquid supply holes at the same position along the longitudinal direction in the first region are arranged at intervals of approximately 180 degrees when viewed along the axial direction.

10. A cleaning member assembly comprising:
the cleaning member attaching part according to claim 1; and
a cleaning member provided on a surface of the cleaning member attaching part.

11. A substrate cleaning apparatus comprising:
a substrate support part to hold a substrate;
a cleaning member assembly having a cleaning member attaching part according to claim 1 and a cleaning member provided on a surface of the cleaning member attaching part; and
a cleaning member holding part that holds the cleaning member assembly.

12. A cleaning member assembly comprising:
a unit main body; and
a plurality of nodules that projects outward from the unit main body, wherein
the unit main body has:
a gap that extends therein; and
a plurality of cleaning liquid supply holes that communicates with the gap and discharges cleaning liquid toward the unit main body or the nodules,
the gap is configured such that the cleaning liquid flows in from a first end part side, and
an area proportion of the cleaning liquid supply holes in a second region on a second end part side opposite to a first end part to a surface of the main body is larger than an area proportion of the cleaning liquid supply holes in a first region on the first end part side to the surface of the main body.

13. The cleaning member assembly according to claim 12, wherein the nodules are formed by being molded on the unit main body.
